(19) United States
(12) Patent Application Publication
(10) Pub. No.: US 2020/0384636 A1
(43) Pub. Date: Dec. 10, 2020

(54) DUAL PITCH END EFFECTOR ROBOT APPARATUS, DUAL PITCH LOAD LOCKS, SYSTEMS, AND METHODS

(71) Applicant: Applied Materials, Inc., Santa Clara, CA (US)

(72) Inventors: Karuppasamy Muthukamatchy, Madurai (IN); Rajkumar Thanu, Santa Clara, CA (US); Eran Weiss, Sunnyvale, CA (US); Jeffrey C. Hudgens, San Francisco, CA (US); Chandrakant M. Sapkale, Karnataka (IN)

(21) Appl. No.: 16/434,916

(22) Filed: Jun. 7, 2019

(51) Int. Cl. B25J 9/04; B25J 9/16; B25J 17/02; B25J 18/00; H01L 21/67; H01L 21/677

(52) U.S. Cl. CPC B25J 9/042; B25J 9/1653; H01L 21/67742; B25J 18/005; H01L 21/67201; B25J 17/0283

(57) ABSTRACT

A robot apparatus may include a first arm assembly configured to rotate about a first rotational axis. The first arm assembly may include a first end effector and a second end effector spaced by a first end effector pitch. A second arm assembly may be configured to rotate about the first rotational axis. The second arm assembly may include a third end effector and a fourth end effector spaced by a second end effector pitch, wherein the second end effector pitch is different than the first end effector pitch. Other apparatus, electronic device processing systems, and methods are disclosed.

### FIELD

Embodiments of the present application relate to robots including multiple end effectors and electronic device processing devices and methods including robots with multiple end effectors.

### BACKGROUND

Processing of substrates in semiconductor electronic device manufacturing may require a combination of different processes applied in the same substrate processing system. For example, the processes may include chemical vapor deposition/atomic layer deposition (CVD/ALD) and physical vapor deposition (PVD) applied within the same tool or platform. These processes may be applied using different configurations of processing chambers coupled to a transfer chamber. Robots are located in the transfer chamber and are configured to move substrates between the various processing chambers.

### SUMMARY

In some embodiments, a robot apparatus is provided. The robot apparatus includes a first upper arm configured to rotate about a first rotational axis; a first forearm rotatably coupled to the first upper arm at a second rotational axis; a first wrist member rotatably coupled to the first forearm at a third rotational axis; a first end effector and a second end effector coupled to the first wrist member and spaced by a first end effector pitch; a second upper arm configured to rotate about the first rotational axis; a second forearm rotatably coupled to the second upper arm at a fourth rotational axis; a second wrist member rotatably coupled to the second forearm at a fifth rotational axis; and a third end effector and a fourth end effector coupled to the second wrist member and spaced by a second end effector pitch, the second end effector pitch being different than the first end effector pitch.

In other embodiments, an electronic device processing system is provided. The electronic device processing system includes a transfer chamber; one or more process chambers coupled to the transfer chamber; first dual processing locations located in one or more process chambers, the first dual processing locations being spaced by a first processing distance; second dual processing locations located in one or more process chambers, the second dual processing locations being spaced by a second processing distance, the second processing distance being different than the first processing distance; a robot apparatus at least partially located within the transfer chamber, the robot apparatus comprising: a first arm assembly configured to rotate about a first rotational axis and including a first end effector and a second end effector spaced by a first end effector pitch, wherein the first end effector pitch is equal to the first processing distance, and a second arm assembly configured to rotate about the first rotational axis and including a third end effector and a fourth end effector spaced by a second end effector pitch, wherein the second end effector pitch is equal to the second processing distance.

In other embodiments, an electronic device processing system is provided. The electronic device processing system includes a transfer chamber; one or more process chambers coupled to the transfer chamber; first dual processing locations located in one or more process chambers, the first dual processing locations being spaced by a first processing distance; second dual processing locations located in one or more process chambers, the second dual processing locations being spaced by a second processing distance, the second processing distance being different than the first processing distance; a robot apparatus at least partially located within the transfer chamber, the robot apparatus comprising a first arm assembly configured to rotate about a first rotational axis and including a first end effector and a second end effector spaced by a first end effector pitch, wherein the first end effector pitch is equal to the first processing distance, and a second arm assembly configured to rotate about the first rotational axis and including a third end effector and a fourth end effector spaced by a second end effector pitch, wherein the second end effector pitch is equal to the second processing distance; a factory interface; and a load lock chamber coupled between the factory interface and the transfer chamber, wherein the load lock chamber includes dual transfer locations, each configured to receive a substrate, the dual transfer locations configured to move between a first configuration where the dual transfer locations are spaced a distance equal to the first end effector pitch and a second configuration where the dual transfer locations are spaced a distance equal to the second end effector pitch.

In other embodiments, a load lock apparatus coupleable between a factory interface and a transfer chamber is provided. The a load lock apparatus includes dual transfer locations, each of the dual transfer locations configured to receive a substrate, the dual transfer locations configured to move between a first configuration where the dual transfer locations are spaced a distance equal to a first pitch and a second configuration where the dual transfer locations are spaced a distance equal to a second pitch, wherein the first pitch is different than the second pitch.

In yet other embodiments, a method of transferring substrates is provided. The method includes providing a robot apparatus comprising a first arm assembly including a first end effector and a second end effector spaced by a first end effector pitch, and a second arm assembly including a third end effector and a fourth end effector spaced by a second end effector pitch, wherein the first end effector pitch is different than the second end effector pitch; exchanging substrates from first dual processing locations spaced by a first processing distance in a process chamber with the first end effector and the second end effector spaced by the first end effector pitch; and exchanging substrates from second dual processing locations spaced by a second processing distance in the process chamber with the third end effector and the fourth end effector spaced by the second end effector pitch.

Numerous other aspects and features are provided in accordance with these and other embodiments of the disclosure. Other features and aspects of embodiments of the disclosure will become more fully apparent from the following detailed description, the claims, and the accompanying drawings.

### BRIEF DESCRIPTION OF DRAWINGS

The drawings, described below, are for illustrative purposes only and are not necessarily drawn to scale. The drawings are not intended to limit the scope of the disclosure in any way. Wherever possible, the same or like reference numbers will be used throughout the drawings to refer to the same or like parts.

FIG. 1 illustrates a schematic top view of a substrate processing system including a dual pitch robot apparatus located in a transfer chamber of a main frame according to the disclosed embodiments.

FIG. 2A illustrates a schematic top view of a load lock with dual transfer locations in a first configuration and spacing according to the disclosed embodiments.

FIG. 2B illustrates a schematic top view of the load lock of FIG. 2A with the dual transfer locations in a second configuration and spacing according to the disclosed embodiments.

FIG. 3A illustrates an isometric view of a robot apparatus including multiple end effector pairs having different pitches according to the disclosed embodiments.

FIG. 3B illustrates a top plan view of a robot apparatus including the multiple end effectors according to the disclosed embodiments.

### DETAILED DESCRIPTION

Reference will now be made in detail to the example embodiments provided, which are illustrated in the accompanying drawings. Features of the various embodiments described herein may be combined with each other unless specifically noted otherwise.

Processing of substrates in semiconductor electronic device manufacturing may require a combination of different processes applied in the same substrate processing system. For example, the processes within a tool may include chemical vapor deposition/atomic layer deposition (CVD/ALD) and physical vapor deposition (PVD). These processes may be applied using different configurations of processing chambers located within the substrate processing system. A robot is located in the substrate processing system (e.g., in a transfer chamber of a mainframe, and is configured to move substrates between the processing chambers.

In some embodiments, a substrate processing system may be configured to perform chemical vapor deposition/atomic layer deposition (CVD/ALD) processes. The substrate processing system may also perform physical vapor deposition (PVD) processes. The CVD/ALD processes may be performed in CVD/ALD process chambers and the PVD processes may be performed in PVD process chambers. The spacing between respective processing locations for each process may be different. For example, The CVD/ALD process chambers may include process locations spaced at a first distance (a first pitch) and PVD process chambers may include process locations spaced at a second distance (at a second pitch). In some embodiments, the first pitch between centers of the process locations may be in a range from 0.45 m to 0.65 m and the second pitch between centers of process locations may be in a range from 0.60 m to 0.80 m. In some embodiments, the first pitch between centers of the process locations may be about 22 inches (about 0.56 m) and the second pitch between centers of process locations may about 28 inches (about 0.70 m). Other distances or processes are possible.

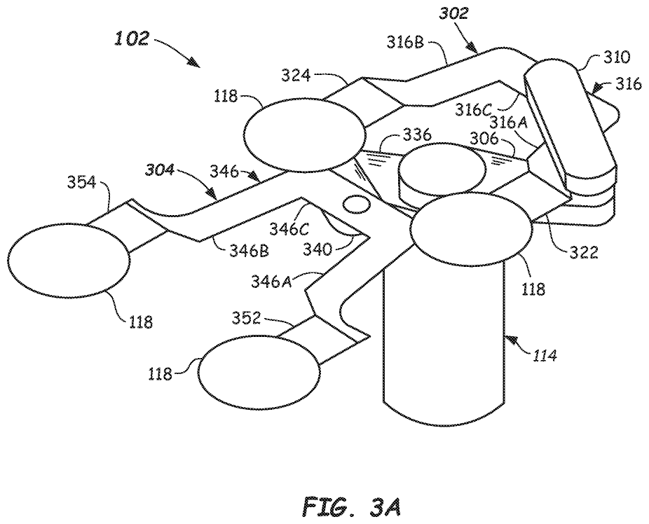

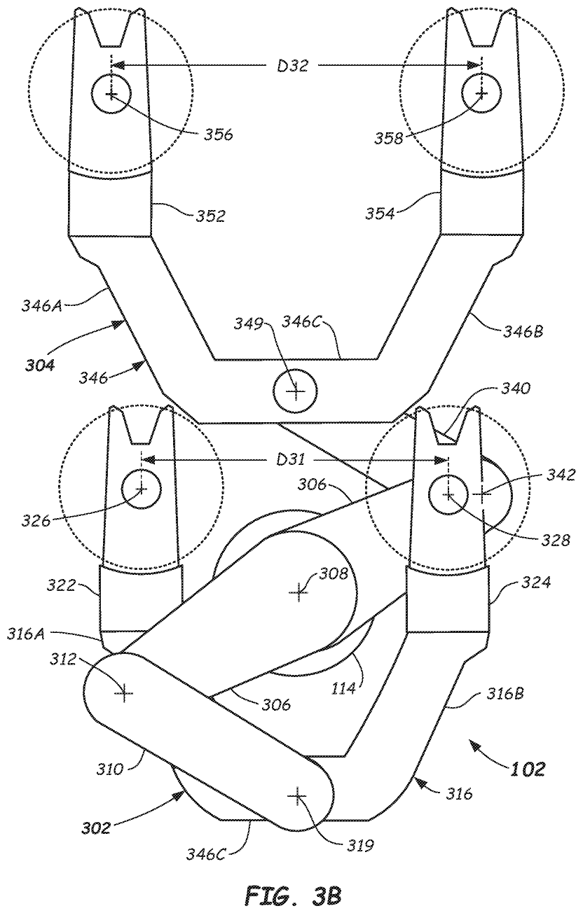

The substrate processing system may include a robot including end effectors that may access substrates located at processing locations having the first pitch and the second pitch. In addition, the distances between centers of dual slit valves though which the robot apparatus may access a process chamber may of a sufficient width to accommodate having different pitches D31 and D32 between respective end effectors as shown in FIGS. 3A and 3B.

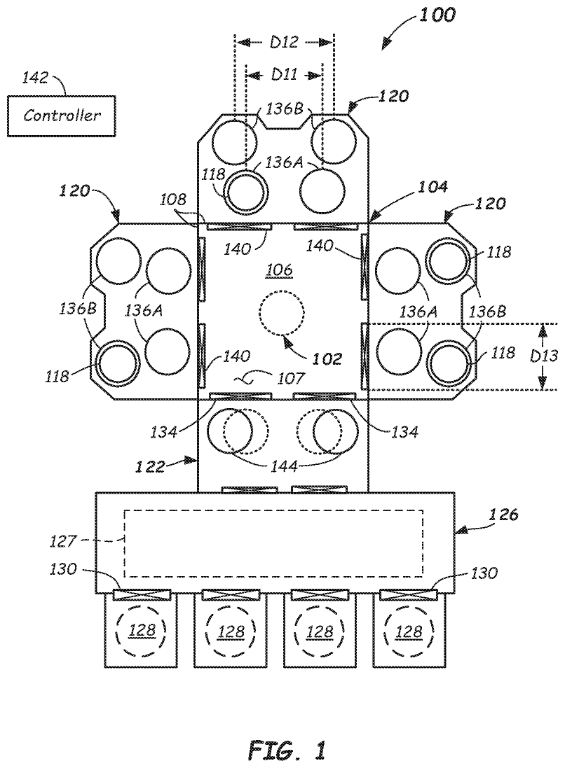

Some substrate processing systems with different process chamber configurations may include robot apparatus with limited ability to access the different process chambers. Example embodiments of robots including different pitches between end effectors are described herein with reference to FIGS. 1-3B.

Reference is now made to FIG. 1, which illustrates a schematic top view of a substrate processing system 100 including a robot apparatus 102 (shown as a dotted circle in FIG. 1) according to disclosed embodiments. The substrate processing system 100 may include a main frame 104 including a transfer chamber 106 formed by walls thereof. The transfer chamber 106 may include a floor 107 and a plurality of facets 108 and may be configured to operate in a vacuum, for example. The robot apparatus 102 may be at least partially located in the transfer chamber 106 and may be configured to be operable therein. The robot apparatus 102 may include a base 314 (FIG. 3B) that is configured to be attached to a wall (e.g., the floor 107) of the transfer chamber 106.

The robot apparatus 102 may be configured to pick and/or place substrates 118 (sometimes referred to as a “wafers” or “semiconductor wafers”) to and from different destinations. The destinations may be chambers coupled to the transfer chamber 106. For example, the destinations may be one or more process chambers 120 and a load lock apparatus 122 that may be coupled to the plurality of facets 108 of the transfer chamber 106. The main frame 104 may include more or fewer process chambers 120 than illustrated in FIG. 1 and more than one load lock apparatus 122.

The process chambers 120 may be configured to carry out any number of process steps on the substrates 118, such as deposition, oxidation, nitration, etching, polishing, cleaning, lithography, or the like. The load lock apparatus 122 may be configured to interface with a factory interface 126. The factory interface 126 may include a load/unload robot 127 (shown as a dotted box) configured to transport substrates 118 to and from substrate carriers 128 (e.g., Front Opening Unified Pods (FOUPs)) docked at load ports 130 of the factory interface 126. Another load/unload robot may transfer the substrates 118 between the substrate carriers 128 and the load lock apparatus 122 in any sequence or order.

One or more process chambers 120 may include first dual processing locations 136A and second dual processing locations 136B on which substrates 118 may be placed for processing. The first dual processing locations 136A within one or more of the process chambers 120 may have processing centers that are spaced by a first processing distance D11. The second dual processing locations 136B within one or more of the process chambers 120 may have centers that are spaced by a second processing distance D12. The second processing distance D12 is different than the first processing distance D11. For example, the first processing distance D11 may be less than the second processing distance D12. In other embodiments, the first processing distance D11 may be greater than the second processing distance D12.

The first dual processing locations 136A and the second dual processing locations 136B within one or more of the process chambers 120 may be accessed by the robot apparatus 102 through slit valves 140. The processing chambers 120 may be affixed to the facets 108 such as to align with the slit valves 140 located on the facets 108. The slit valves 140 may have a slit valve width D13 that allows the robot apparatus 102 to access both the first dual processing locations 136A and the second dual processing locations 136B within the process chambers 120.

In some embodiments, the first processing distance D11 may be in a range from 0.45 m to 0.65 m and the second processing distance D12 may be in a range from 0.60 m to 0.80 m. In other embodiments, the first processing distance D11 may be about 22 inches (about 0.56 m) and the second processing distance D12 may be about 28 inches (about 0.70 m).

A controller 142 may be in communication with the robot apparatus 102. The robot apparatus 102 may be controlled by suitable commands from the controller 142. The controller 142 may also control the slit valves 140 and other components and processes taking place within the main frame 104 and processing chambers.

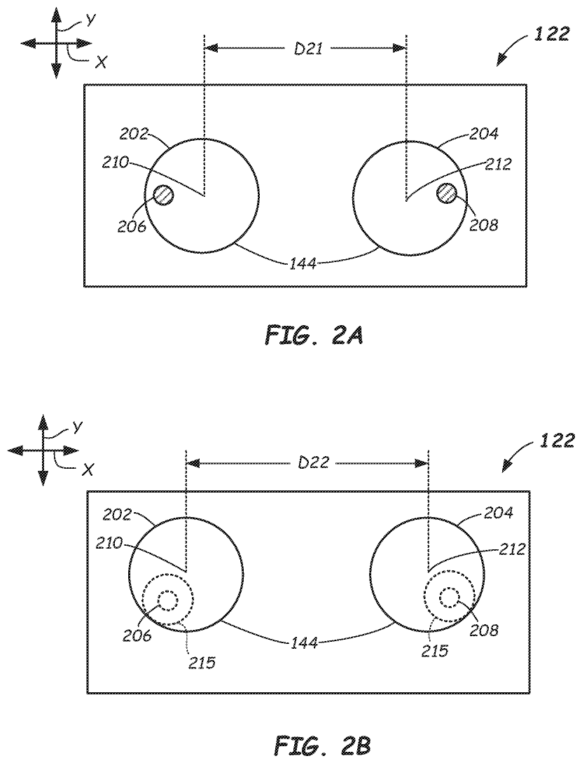

The load lock apparatus 122 may include dual transfer locations 144 on which substrates 118 may be placed for transfer into and out of the transfer chamber 106. Additional reference is made to FIG. 2A, which illustrates a top view of the load lock apparatus 122 with the dual transfer locations 144 in a first configuration according to the disclosed embodiments. Additional reference is made to FIG. 2B, which illustrates a top view of the load lock apparatus 122 with the dual transfer locations 144 in a second configuration according to the disclosed embodiments.

The dual transfer locations 144 within the load lock apparatus 122 may be rotated to effectively adjust a transfer distance (spacing) between centers of the dual transfer locations 144. The dual transfer locations 144 within a load lock chamber 122 may be accessed by the robot apparatus 102 through dual slit valves 134 in one of the facets 108 (e.g., the front facet). The dual slit valves 134 are of a width that provides for simultaneous access to the dual transfer locations 144 within the load lock apparatus 122 with either pitch of the end effectors (FIGS. 3A-3B). Slit valves may be provided on the EFEM side, but that can be a standard width and spacing.

The dual transfer locations 144 may include a first platen 202 and a second platen 204 positioned side-by-side. The first platen 202 may rotate in the X-Y plane about a first fixed point 206 (e.g., about a shaft coupled to the first platen 202). Similarly, the second platen 204 may rotate in the X-Y plane about a second fixed point 208 (e.g., a second shaft coupled to the second platen 204). The first fixed point 206 may be offset from a center 210 of the first platen 202. The second fixed point 208 may be offset from a center 212 of the second platen 204. The first and second platens 202, 204 may be rotated using one or more motors 215 (shown dotted) mounted below the platens 202, 204 and coupled to respective shafts. The motors 215 receive control signals from the controller 142. A drive system may be used in some embodiments including, for example, a chain(s), belt(s), or other drive connector(s) coupled to the motors 215 or even a single motor in some embodiments. The platens 202, 204 may include suitable supports to receive and support substrates thereon during transfer through the load lock apparatus 122. The supports (not shown) can be provided at vertical locations corresponding to the vertical spacing between the planes of operation of the first arm assembly 302 and the second arm assembly 304 (see FIGS. 3A and 3B). Any suitable configuration of the supports can be used.

In a first configuration, the first and second platens 202, 204 are rotated in opposite directions. For example, the first platen 202 may be rotated clockwise to its first position and the second platter 204 may be rotated counter clockwise to its second position. In the first configuration, a distance D21 between the centers 210, 212 of the first and second platters 202, 204 may be equal to the first processing distance D11 between the first dual processing locations 136A (FIG. 1).

The rotation of each the first platen 202 and the second platen 204 may transition the dual transfer locations 144 between the first configuration illustrated in FIG. 2A and the second configuration illustrated in FIG. 2B. As shown in FIG. 2B, in the second configuration, the first platen 202 and the second platen 204 may be rotated in opposite directions. Specifically, the first platen 202 may be rotated counterclockwise to its second position and the second platen 204 may be rotated clockwise to its second position. In the second configuration, a distance D22 between the centers 210, 212 of the first and second platters 202, 204 may be equal to the second processing distance D12 between the second dual processing locations 136B (FIG. 1), wherein D22 can be different than (greater than) D12.

In some embodiments, the first and second platens 202, 204 may rotate 45 degrees while transitioning between the first configuration and the second configuration. This rotation results in the centers 210, 212 being displaced 76.3 millimeters in the X-direction and 31.5 millimeters in the Y-direction. The first and second configurations may be constrained by stops or by rotation sensors providing rotational feedback information.

Additional reference is made to FIG. 3A, which illustrates an isometric view of an embodiment of the robot apparatus 102 according to disclosed embodiments. Additional reference is also made to FIG. 3B, which illustrates top plan view of an embodiment of the robot apparatus 102 according to disclosed embodiments. The robot apparatus 102 may include a first arm assembly 302 and a second arm assembly 304. In some embodiments, portions of the first arm assembly 302 and portions of the second arm assembly 304 may operate on different planes, one above the other.

The first arm assembly 302 may include a first upper arm 306 configured to rotate about a first rotational axis 308. For example, one or more motors (not shown) located in the base 114 may rotate the first upper arm 306 about the first rotational axis 308. A first forearm 310 may be rotatably coupled to the first upper arm 306 at a second rotational axis 312. The second rotational axis 312 may be spaced from the first rotational axis 308. A first wrist member 316 may be rotatably coupled to the first forearm 310 at a third rotational axis 319. The third rotational axis 319 may be spaced from the second rotational axis 312.

A first end effector 322 and a second end effector 324 may be coupled to the first wrist member 316. The first end effector 322 may be spaced from the second end effector 324 by a first pitch D31. In some embodiments, the first pitch D31 is measured between a first center point 326 of the first end effector 322 and a second end point 328 of the second end effector 324. In some embodiments, a centerline of the first end effector 322 may be parallel to a centerline of the second end effector 324. In some embodiments, the first pitch D31 can be substantially equal to D11 and may also be substantially equal to D21.

The second arm assembly 304 may include a second upper arm 336 configured to rotate about the first rotational axis 308. For example, one or more motors (not shown) located in the base 114 may rotate the second upper arm 336 about the first rotational axis 308. A second forearm 340 may be rotatably coupled to the second upper arm 336 at a fourth rotational axis 342. The fourth rotational axis 342 may be spaced from the first rotational axis 308. A second wrist member 346 may be rotatably coupled to the second forearm 340 at a fifth rotational axis 349. The fifth rotational axis 349 may be spaced from the fourth rotational axis 342.

A third end effector 352 and a fourth end effector 354 may be coupled to the second wrist member 346. The third end effector 352 may be spaced from the fourth end effector 354 by a second pitch D32. In some embodiments, the second pitch D32 is measured between a first center point 356 of the third end effector 352 and a second center point 358 of the fourth end effector 354. The first pitch D31 may be different than the second pitch D32. For example, the first pitch D31 may be less than the second pitch D32. In some embodiments, the first end effector 322, the second end effector 324, the third end effector 352, and the fourth end effector 354 may be substantially similar or identical. In some embodiments, a centerline of the third end effector 352 may be parallel to a centerline of the fourth end effector 354. In some embodiments, the second pitch D32 can be substantially equal to D12 and may also be substantially equal to D22.

In some embodiments, the first wrist member 316 may be U-shaped. The U-shaped first wrist member 316 may include a first leg 316A coupled to the first end effector 322, a second leg 316B coupled to the second end effector 324, and a boom 316C coupled between the first leg 316A and the second leg 316B. In some embodiments, the second wrist member 346 may be U-shaped. The U-shaped second wrist member 346 may include a first leg 346A coupled to the third end effector 352, a second leg 346B coupled to the fourth end effector 354, and a boom 346C coupled between the first leg 346A and the second leg 346B.

In some embodiments, the first pitch D31 may be in a range from 0.45 m to 0.65 m and the second pitch D32 may be in a range from 0.60 m to 0.80 m. In some embodiments, the first pitch D31 may be about 22 inches (about 0.56 m) and the second pitch D32 may be about 28 inches (about 0.70 m). In some embodiments, the robot apparatus 102 includes a first motor (not shown) configured to rotate the first upper arm 306 and a second motor (not shown) configured to rotate the first forearm 310 and the first wrist member 316. Other motors may be provided.

In some embodiments, the distances corresponding to D11, D21, and the distance D31 are equal or substantially similar. In some embodiments, the distance corresponding to D12, the distance D23, and the distance D32 are equal or substantially similar. Thus, the first end effector 322 and the second end effector 324 of the first arm assembly 302 may access substrates 118 that are spaced the D11 and D12 from each other. In addition, the third end effector 352 and the fourth end effector 354 may access substrates 118 that are spaced by D12 and the distance D22 from each other.

During operation of the substrate processing system 100, the transfer locations 144 in the load lock chamber 122 may be moved to receive substrates 118 from the factory interface 126. Substrates 118 may then be transferred from the factory interface 126 to the transfer locations 144 in the load lock apparatus 122. The transfer locations 144 may then be moved so that the substrates 118 are spaced by either the pitch D21 or the pitch D22. The first arm assembly 302 or the second arm assembly 304 of the robot apparatus 102 may retrieve the substrates 118 from the load lock apparatus 122. For example, if the substrates 118 are spaced the distance D21, then the first arm assembly 302 may retrieve the substrates 118. If the substrates 118 are spaced the distance D22, then the second arm assembly 304 may retrieve the substrates 118.

The robot apparatus 102 may also transport the substrates 118 to appropriate locations. For example, substrates 118 transported by the first arm assembly 302 may be placed on the first dual processing locations 136A. Substrates transported by the second arm assembly 304 may be placed on the second dual processing locations 136B. The reverse process may be performed to transport substrates 118 from the processing chambers 120 to the factory interface 126.

In yet other embodiments, a method of transferring substrates is provided. The method includes providing a robot apparatus comprising a first arm assembly 302 including a first end effector 322 and a second end effector 324 spaced by a first end effector pitch D31, and a second arm assembly 302 including a third end effector 352 and a fourth end effector 354 spaced by a second end effector pitch D32, wherein the first end effector pitch D31 is different than the second end effector pitch D32; exchanging substrates from first dual processing locations 136A spaced by a first processing distance D11 in a process chamber 120 with the first end effector 322 and the second end effector 324 spaced by the first end effector pitch D31; and exchanging substrates from second dual processing locations 136B spaced by a second processing distance D21 in the process chamber 120 with the third end effector 352 and the fourth end effector 352 spaced by the second end effector pitch D32.

The foregoing description discloses example embodiments of the disclosure. Modifications of the above-disclosed apparatus, systems, and methods which fall within the scope of the disclosure will be readily apparent to those of ordinary skill in the art. Accordingly, while the present disclosure has been disclosed in connection with example embodiments, it should be understood that other embodiments may fall within the scope of the disclosure, as defined by the claims.

What is claimed is:

1. A robot apparatus, comprising:
a first upper arm configured to rotate about a first rotational axis;
a first forearm rotatably coupled to the first upper arm at a second rotational axis;
a first wrist member rotatably coupled to the first forearm at a third rotational axis;
a first end effector and a second end effector coupled to the first wrist member and spaced by a first end effector pitch;
a second upper arm configured to rotate about the first rotational axis;
a second forearm rotatably coupled to the second upper arm at a fourth rotational axis;
a second wrist member rotatably coupled to the second forearm at a fifth rotational axis; and
a third end effector and a fourth end effector coupled to the second wrist member and spaced by a second end effector pitch, the second end effector pitch being different than the first end effector pitch.

2. The robot apparatus of claim 1, wherein the first wrist member is U-shaped and includes a first leg coupled to the first end effector, a second leg coupled to the second end effector, and a boom coupled between the first leg and the second leg.

3. The robot apparatus of claim 1, wherein the second wrist member is U-shaped and includes a first leg coupled to the third end effector, a second leg coupled to the fourth end effector, and a boom coupled between the first leg and the second leg.

4. The robot apparatus of claim 1, wherein a centerline of the first end effector is parallel to a centerline of the second end effector.

5. The robot apparatus of claim 1, wherein a centerline of the third end effector is parallel to a centerline of the fourth end effector.

6. The robot apparatus of claim 1, wherein the first end effector pitch is in a range from 0.45 m to 0.65 m and the second end effector pitch is in a range from 0.60 m to 0.80 m.

7. The robot apparatus of claim 1, wherein the first end effector pitch is about 22 inches (about 0.56 m) and the second end effector pitch is about 28 inches (about 0.70 m).

8. An electronic device processing system, comprising:
a transfer chamber;
one or more process chambers coupled to the transfer chamber;
first dual processing locations located in one or more process chambers, the first dual processing locations being spaced by a first processing distance;
second dual processing locations located in one or more process chambers, the second dual processing locations being spaced by a second processing distance, the second processing distance being different than the first processing distance;
a robot apparatus at least partially located within the transfer chamber, the robot apparatus comprising:
a first arm assembly configured to rotate about a first rotational axis and including a first end effector and a second end effector spaced by a first end effector pitch, wherein the first end effector pitch is equal to the first processing distance; and
a second arm assembly configured to rotate about the first rotational axis and including a third end effector and a fourth end effector spaced by a second end effector pitch, wherein the second end effector pitch is equal to the second processing distance.

9. The electronic device processing system of claim 8, wherein the first processing distance is in a range from 0.45 m to 0.65 m and the second processing distance is in a range from 0.60 m to 0.80 m.

10. The electronic device processing system of claim 8, wherein the first processing distance is about 22 inches (about 0.56 m) and the second processing distance is about 28 inches (about 0.70 m).

11. The electronic device processing system of claim 8, wherein the first arm assembly includes:
a first upper arm configured to rotate about the first rotational axis;
a first forearm rotatably coupled to the first upper arm at a second rotational axis; and
a first wrist member rotatably coupled to the first forearm at a third rotational axis, wherein the first end effector and the second end effector are coupled to the first wrist member.

12. The electronic device processing system of claim 11, wherein the first wrist member is U-shaped and includes a first leg coupled to the first end effector, a second leg coupled to the second end effector, and a boom coupled between the first leg and the second leg.

13. The electronic device processing system of claim 8, wherein the second arm assembly includes:
a second upper arm configured to rotate about the first rotational axis;
a second forearm rotatably coupled to the second upper arm at a fourth rotational axis; and
a second wrist member rotatably coupled to the second forearm at a fifth rotational axis, wherein the third end effector and the fourth end effector are coupled to the second wrist member.

14. The robot apparatus of claim 13, wherein the second wrist member is U-shaped and includes a first leg coupled to the third end effector, a second leg coupled to the fourth end effector, and a boom coupled between the first leg and the second leg.

15. The electronic device processing system of claim 8, further comprising a factory interface configured to have one or more substrate carriers coupled thereto.

16. The electronic device processing system of claim 15, further comprising a load lock coupled between the transfer chamber and the factory interface.

17. The electronic device processing system of claim 16, wherein the load lock includes dual transfer locations, each configured to receive a substrate, the dual transfer locations configured to move between a first configuration where the dual transfer locations are spaced a distance equal to the first end effector pitch and a second configuration where the dual transfer locations are spaced a distance equal to the second end effector pitch.

18. An electronic device processing system, comprising:
a transfer chamber;
one or more process chambers coupled to the transfer chamber;
first dual processing locations located in one or more process chambers, the first dual processing locations being spaced by a first processing distance;
second dual processing locations located in one or more process chambers, the second dual processing locations being spaced by a second processing distance, the second processing distance being different than the first processing distance;
a robot apparatus at least partially located within the transfer chamber, the robot apparatus comprising:
a first arm assembly configured to rotate about a first rotational axis and including a first end effector and a second end effector spaced by a first end effector pitch, wherein the first end effector pitch is equal to the first processing distance; and
a second arm assembly configured to rotate about the first rotational axis and including a third end effector and a fourth end effector spaced by a second end effector pitch, wherein the second end effector pitch is equal to the second processing distance;
a factory interface; and
a load lock coupled between the factory interface and the transfer chamber, wherein the load lock includes dual transfer locations, each configured to receive a substrate, the dual transfer locations configured to move between a first configuration where the dual transfer locations are spaced a distance equal to the first end effector pitch and a second configuration where the dual transfer locations are spaced a distance equal to the second end effector pitch.

19. A load lock apparatus coupleable between a factory interface and a transfer chamber, comprising:
dual transfer locations, each of the dual transfer locations configured to receive a substrate, the dual transfer locations configured to move between a first configuration where the dual transfer locations are spaced a distance equal to a first pitch and a second configuration where the dual transfer locations are spaced a distance equal to a second pitch, wherein the first pitch is different than the second pitch.

20. A method of transferring substrates, comprising:
providing a robot apparatus comprising a first arm assembly including a first end effector and a second end effector spaced by a first end effector pitch, and a second arm assembly including a third end effector and a fourth end effector spaced by a second end effector pitch, wherein the first end effector pitch is different than the second end effector pitch;
exchanging substrates from first dual processing locations spaced by a first processing distance in a process chamber with the first end effector and the second end effector spaced by the first end effector pitch; and
exchanging substrates from second dual processing locations spaced by a second processing distance in the process chamber with the third end effector and the fourth end effector spaced by the second end effector pitch.
